(19) United States
(12) Patent Application Publication
(10) Pub. No.: US 2014/0242747 A1
(43) Pub. Date: Aug. 28, 2014

(54) Thin Film Deposition of Materials by External Induced Release from a Ribbon Tape

(71) Applicant: Applied Nanotech Holdings, Inc., Austin, TX (US)

(72) Inventors: Zvi Yaniv, Austin, TX (US); James P. Novak, Austin, TX (US)

(21) Appl. No.: 14/348,812

(22) PCT Filed: Oct. 4, 2012
(86) PCT No.: PCT/US12/58616

§ 371 Date: Mar. 31, 2014

Related U.S. Application Data
(60) Provisional application No. 61/542,981, filed on Oct. 4, 2011.

(51) Int. Cl. H01L 21/285; H01L 31/18

(52) U.S. Cl. CPC H01L 21/2855; H01L 31/18
USPC 438/98; 438/597

(57) ABSTRACT

A process where a printed ink is placed onto a sacrificial ribbon. The ink is then converted to a metal film and transferred to a substrate, such as a silicon solar cell at very low temperatures. Further low-temperature processing may be utilized to form an ohmic contact. This process provides the speed and low-cost structure of ink and paste based processing with the diffusion control of vacuum deposited films.

This application claims priority to U.S. Provisional Application Ser. No. 61/542,981, which is hereby incorporated by reference herein.

### BACKGROUND INFORMATION AND SUMMARY

The printed electronics industry is developing rapidly to provide an additive method of manufacturing that can increase speed, reduce process steps, and show significant savings in materials usage. The additive print process requires both new ink and paste materials as well as proper printing and curing methods to convert the inks and pastes to a suitable film on a substrate.

Functional inks and pasts exist that cover conductive, resistive, and dielectric insulating applications. These inks and pastes can be used for contact and non-contact printing. Contact and non-contact printing vary in the print speed, material transfer volume, resolution of the printed pattern, volume capacity of the apparatus, and material requirements of the substrates to be printed on.

Contact type printing involves physical contact between the print apparatus and the substrate. Examples of contact type printing include flexographic, gravure, and screen printing. Non-contact printing transfers the ink, materials without physical contact between the substrate and print apparatus. Examples include spray coatings, aerosolized jet, piezo-electric inkjet, and dispenser pens. Both contact and non-contact printing have limitations on resolution.

In some applications, the contact printing techniques, such as screen printing, can be applicable, and in many industries such as the PCB industry or electronic packaging industry, these techniques are utilized. Screen printing techniques also have been utilized in the solar industry. However, in order to cut the costs of the solar cells based on silicon wafers, these waters must be thinner. As a result, beyond a certain thickness, a silicon water cannot withstand the pressures of contact type printing (e.g., screen printing) before fracturing. Thus, new techniques are needed where the substrate is not contacted. One of them is inkjet printing, which has a lot of advantages, but also has disadvantages. For example, inkjet printing may not be compatible with a roll-to-roll manufacturing process, which may increase the costs. On the other hand, if someone needs to print very precisely in detached locations, inkjet printing can be useful.

Printing using liquid inks and pastes for inkjet or screen printing have limitations on resolution. This is because the liquid physical state can flow and spread on the surface. The exact amount of spreading is dependent on the surface energy of the substrate and that of the ink. Viscosity of the inks and pastes also plays a major role in such spreading. Inks commonly have a viscosity less than 1000 cP and pastes greater than 1000 cP. As an alternative to printing using direct application of inks and pastes, printing in solid form does not have the limitations of spreading.

Metallic printing using ribbons is being utilized in the packaging industry. For example, IIMAK Company has products that use thermal transfer for transferring certain graphic inks from a ribbon to a substrate. Furthermore, a press release of IIMAK presented a ribbon with thermal transfer of a metallic thin film. Some of these ribbons are used, for example, for barcode applications. IIMAK recently introduced an aluminum thermal transfer ribbon. This metallic transfer ribbon is made by evaporating aluminum metal onto a ribbon material with is release layer. When heat is applied to the release layer, the metallic layer is transferred to a nearby substrate. Generally, these metallic layers are very thin (e.g., less than 3,000 angstroms) such that the film will cleave at the edge of the pattern related to the head source. As a result, the resistance of the resulting film is very high resulting in limited applications.

While these printing processes have been well documented, they are novel for use on solar cells. Currently, the application of metallic contact grids to silicon solar cells is dominated by the screen application of metallic pastes. These high-viscosity liquid materials are patterned, onto both the front side as a grid structure, and the back side as a complete coverage to provide electrical contacts to the collector and emitter layers in the silicon solar cell. The pastes must be thermally processed at temperatures exceeding 700° C., and in many cases up to 900° C., to convert the metallic particles in the paste into a sintered metallic conductor. The sintering process provides electrical connection between adjacent, neighboring particles but may not fully melt the particles into a dense film.

The challenge with the sintering of metallic paste techniques is the high temperatures required for processing and forming the electrical contacts. Metallic particles require high temperature for sintering, which can be detrimental to the performance of the solar cell. For example, the front side contacts on silicon solar cells are commonly made using Ag paste. The front side doping of the silicon can he very shallow. In one example, the main wafer is p-type and the top doping layer is n-type. The p-n junction that enables the photovoltaic effect is often very shallow (e.g., less than 2 micrometers in depth from the top surface of the wafer). In extreme cases, the p-n junction depth can be even more shallow (e.g., less than 0.5 μm). When the silver paste is fired in the high temperature furnace, the Ag atoms will diffuse through the silicon. If they diffuse to a depth greater than the depth of the p-n junction, the solar cell performance will be greatly diminished. Such a cell would be considered to have an electrical shunt or short across the p-n junction. Controlling this diffusion depth is a challenge.

The tiring process must overcome multiple mechanisms and kinetic controlled steps. For example, the heating of the film and physical conversion of individual particles to a conductive film can be kinetically slow, often occurring on a time scale of several seconds. In contrast, the formation of an ohmic contact through the process of molten Ag in contact with silicon can be significantly faster. The diffusion of Ag, once the ohmic contact has been established can go past the p-n junction in sub-second time scales. The time scales are accelerated with heat.

Most modern Ag paste materials are tired at greater than 800° C. and less than 900° C. peak temperature. It requires this much heat to sinter the Ag particles in the paste. However, the annealing temperature required for forming an ohmic contact between the contact metal and the silicon is quite low, typically between 300 and 400° C. At these lower temperatures, the diffusion is slowed considerably, and the probability of diffusion based shunts greatly reduced.

This makes the process of Ag sintering challenging to have enough heat and time to sinter the paste, form an electrical contact, but yet limit the heat and time to the point of preventing Ag diffusion and wafer shunting. Often complex firing profiles complete with rapid cooling cycles are used to enable this process.

Modern silicon solar cells structures are quite complex, and therefore the processes to produce them are becoming increasingly difficult. Modern top contact silicon solar cells often use high-resistance emitters which are characterized by low-dopant concentrations in the top layer. The low-dopant concentrations can increase the lifetime of photo-separated charges in the solar cell. Additionally, by making the solar cell dopant layer thinner (shallow when compared to the top surface), the separated charges have a shorter distance to navel to an electrode. This helps with the overall charge collection within the silicon solar cell providing increased solar efficiency.

Examples of silicon solar cells manufactured using, evaporated metal contacts can separate the process of sintering from forming an electrical contact. Examples of evaporated metal can be electron-beam evaporation, physical vapor deposition (PVD), sputtering, etc. While these processes can provide superior results, they are expensive and time consuming. These techniques will increase the overall cost of manufacturing and may not offset the increase in yield or performance.

Embodiments of the present invention describes a process where a printed ink is placed onto a sacrificial ribbon. The ink is then converted to a metal film and transferred to a substrate, such as a silicon solar cell at very low temperatures. Further low-temperature processing may he utilized to form an ohmic contact. This process provides the speed and low-cost structure of ink and paste based processing with the diffusion control of vacuum deposited films.

### BRIEF DESCRIPTION OF THE DRAWINGS

FIG. 1 illustrates a prior art laser transfer process for transferring silver paste from a glass ribbon to a substrate.

FIG. 2 illustrates several examples of using a laser transfer process to transfer a copper in and/or paste from a glass ribbon to a silicon wafer or a glass substrate.

FIGS. 3A-3B illustrate a copper seed layer deposited on a polyimide substrate (FIG. 3A) and its plating to a thickness of approximately 10 micrometers of copper thereon (FIG. 3B).

FIGS. 4A-4B illustrate a diagram for producing a conductive line on a substrate using a transfer process from a flexible ribbon in accordance with embodiments of the present invention.

FIG. 5 illustrates utilizing two or more lasers in a synchronized manner for implementing a transfer process in accordance with embodiments of the present invention.

FIG. 6 illustrates a diagram of transferring features digitally printed on a ribbon to a substrate.

FIG. 7 illustrates a digital image of a copper ink or paste sintered on a substrate using a laser, which shows the width of the sintered line being of a brighter color and approximately 10 micrometers in width.

FIG. 8A illustrates a digital image of a morphology of a properly sintered copper layer.

FIG. 8B illustrates a digital image of a morphology of an unsintered copper ink or paste layer.

FIG. 9 illustrates a digital image showing a morphology of a copper ink or paste sintered in ambient air with at laser showing copper oxide crystallites.

FIG. 10 illustrates a flow diagram of embodiments of the present invention.

### DETAILED DESCRIPTION

Applied Nanotech Holdings, Inc., the assignee of the present invention, has developed, a number of metallic, dielectric, CNT, and other inks and pastes for utilization in the printed electronics and solar industries, such as copper inks and pastes. Numerous patents are pending with respect to the subject, for aluminum pastes and inks, nickel inks and others, which include U.S. Published Patent Application Nos. 2008/0286488, 2009/0242854, and 2010/0000762, which are all hereby incorporated by reference herein. For example, these applications disclose copper inks developed purposely for inkjet printing and photosintering at low temperatures. The sintering methods can vary from thermal sintering, laser sintering, or xenon lamp sintering, and utilize photosintering. Copper pastes have been developed that can be sintered/photosintered in similar ways.

Instead of depositing by vacuum deposition, embodiments of the present invention disclose a metallic layer on a ribbon with a self-release capability (an exterior force that can induce release may be thermal, light, laser, and other equivalent exterior agents utilized for such a release process), where the ink or the paste is printed on the ribbons, and then released onto a substrate.

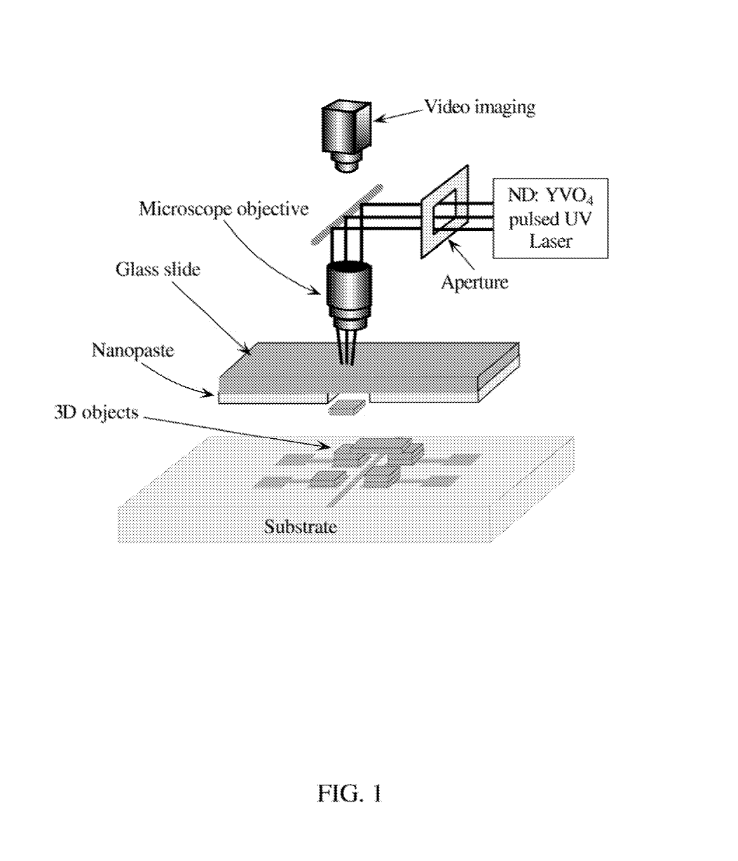

Previously, other organizations demonstrated the laser transfer process principle as shown in FIG. 1 (see J. Want et at, “Adv. Mat.,” Volume 22, Issue 40, 2010, pp. 4462-4466, which is hereby incorporated by reference herein). The problem is that the nano-paste in this work was a silver ink/paste, and the ribbon was an inflexible glass slide. Furthermore, the paste had to remain in a liquid state. According to the foregoing published paper, the local heating of the solvents caused evaporation. The volume expansion of the evaporated solvents pushed the ink off the surface of the glass slide and onto the substrate.

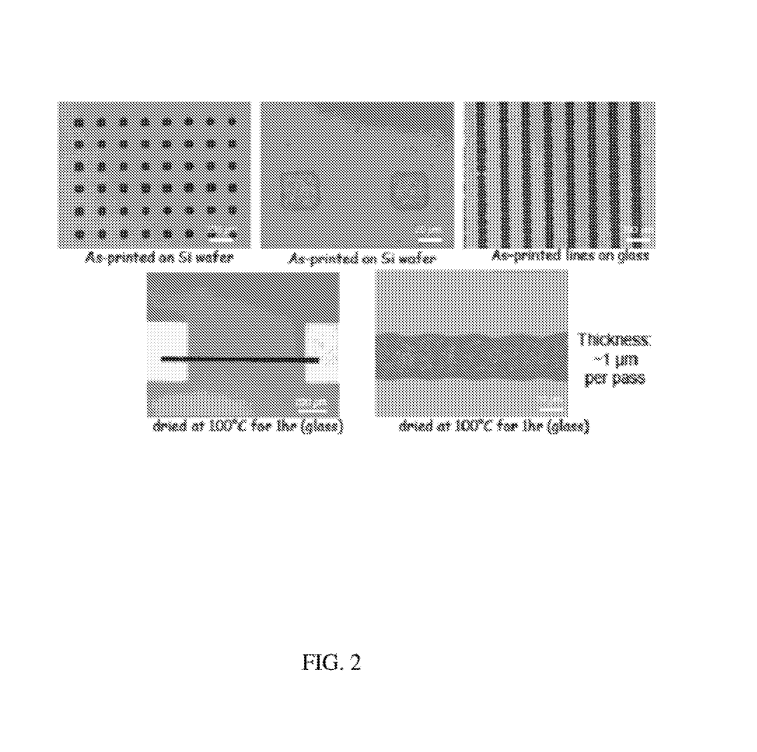

Under a similar principle used by the inventors, but utilizing copper inks/pastes on a glass slide that played a role of a ribbon, copper features were printed on a silicon wafer and on glass, achieving very promising results as shown in FIG. 2. FIG. 2 shows digital images of copper ink/paste materials laser transferred (e.g., using a ND: YV04 pulse laser (355 nanometer, 30 nanosecond pulse, 40-1600 nJ output)). The results in FIG. 2 show the possibilities of coating with inks different kinds of sacrificial ribbons and being able to use an exterior agent (e.g., a UV laser) to transfer from the ribbon to a substrate ink or paste features (i.e., features that are basically in the embodied in inks or pastes) or features that are already embodied in sintered inks and pastes in their final form either metallic or others.

Another aspect is that, in general, when transfer is used from a ribbon to as substrate, the material layer transferred to the substrate is very thin. In some circumstances, this may be useful, but if the purpose is to use the traces transferred onto a substrate as a metallic conductor, thicknesses as large as 20 micrometers or more may be needed.

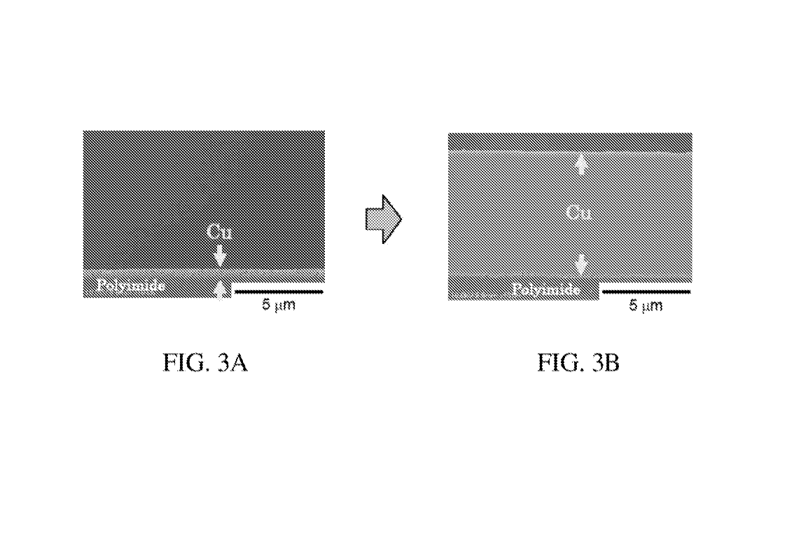

Referring to FIGS. 3A-3B, a solution is to use metallic traces transferred from a ribbon onto a substrate as seed layers for future processes that may lead to obtaining a thicker feature. The seed layer provides a conformal, conductive layer of which a thicker layer of copper may he deposited (e.g., electrofilled) in order to grow the thicker copper layer. For example, a copper seed layer was transferred to a Kapton substrate on which a plating process produced a thick copper layer. FIG. 3A shows a copper seed layer transferred in accordance with embodiments of the present invention onto a polyimide substrate. FIG. 3B shows how a copper layer can be grown, such as using an electro or electroless plating process using the copper seed layer. In this example, the plated copper layer was deposited to a thickness of approximately 10 micrometers, though the present invention is not limited to such as dimension.

As noted above, IIMAK succeeded to realize a ribbon with evaporated aluminum film on it; using a thermal release process they were able to transfer a thin layer of aluminum to another substrate, such as paper, plastic, or glass.

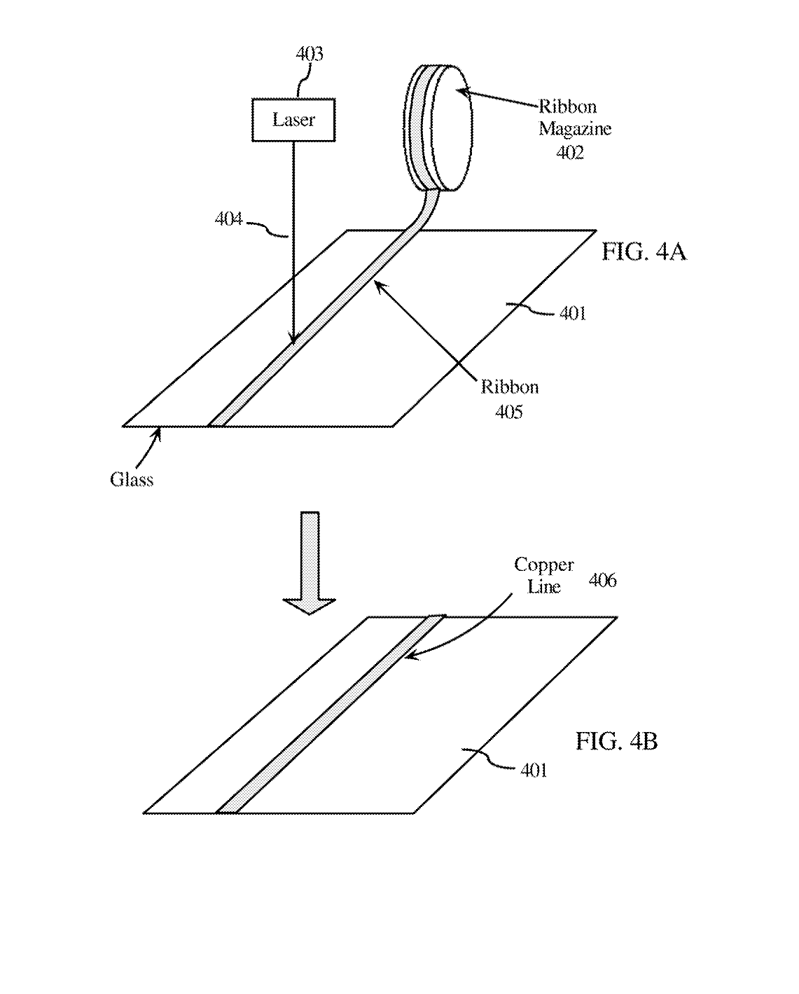

Instead of evaporating or growing on the ribbons different films for transfer processes using exterior agents, embodiments of the present invention coat these materials with an ink layer of the same materials, and then the ink features, or even sintered ink features are transferred directly to the substrate. For example, starting with a ribbon material that has a proper adhesion layer between the copper ink and the substrate, when a laser beam or other detachment means is emitted thereon, a copper line is transferred to another substrate, meaning that in the same process is achieved the transfer and the transformation of the copper ink to copper metal. FIG. 4A illustrates such a process in accordance with embodiments of the present invention whereby a ribbon 405 is dispensed from a ribbon magazine 402 and positioned over a substrate 401, which may be made of glass or some other material. A laser 403 emits a laser beam 404 onto the ribbon 405 to detach a copper ink previously deposited on the ribbon 405 onto the substrate 401. FIG. 4B illustrates the result, which is a copper line 400 deposited with such a process onto the substrate 401. The use of a laser as an exterior agent for detachment is shown, but any other exterior agent for detachment and transfer may be used.

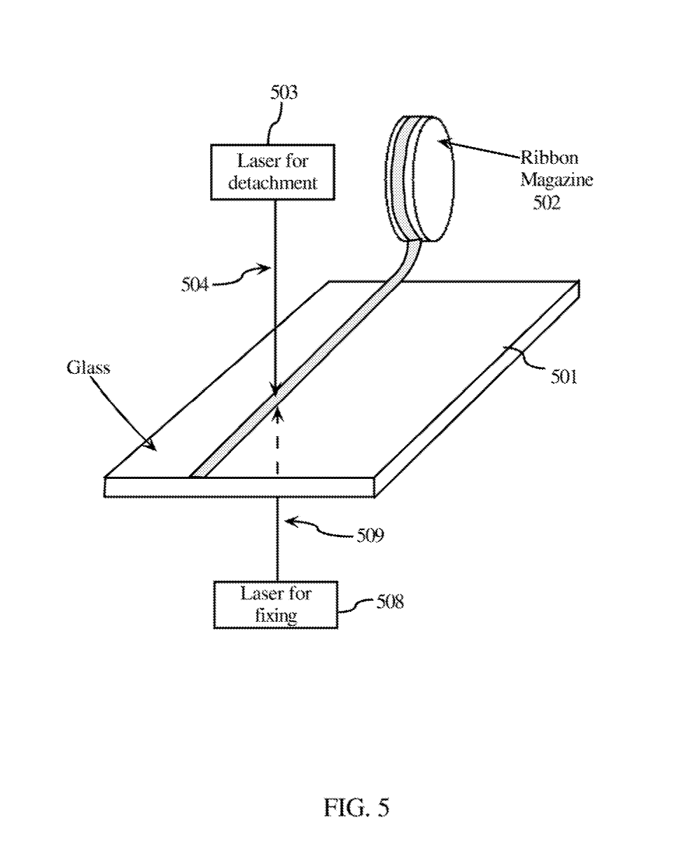

Referring to FIG. 5, two or more lasers may be used that work together (e.g., simultaneously and/or synchronized), with a first laser for the detachment from the ribbon and another for sintering and fixing the transferred material to the substrate. A ribbon with a material such as a deposited copper ink 505 may be dispensed from a ribbon magazine 502 in a position over a substrate 501. As with FIG. 4A, a laser 503 may emit a laser beam 504 for detachment of the copper ink from the ribbon 505 onto the substrate 501, while a second laser 508 emits a laser beam 509 for affixing the deposited features onto the substrate 501. The second laser 508 may perform a sintering and/or photosintering process on the deposited copper ink or paste. Note that a broadband light source (or other detachment means) may be utilized instead, of the laser 508. The substrate in FIG. 5 is glass, but any type of substrate that is compatible with the process can be used.

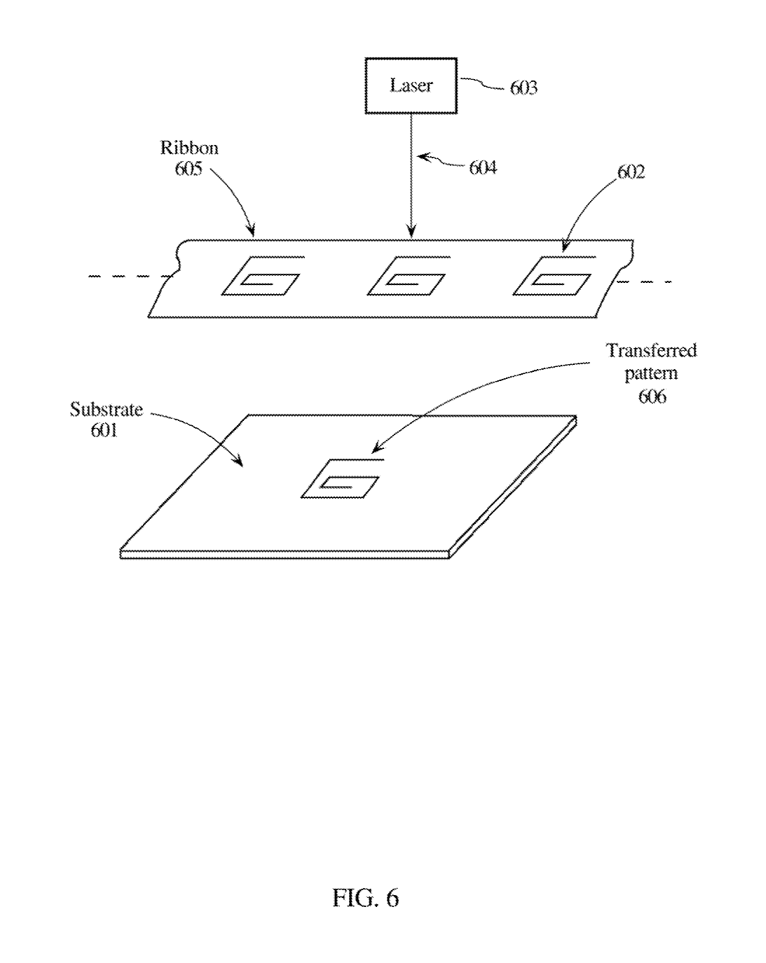

Referring to FIG. 6, a similar embodiment uses inking a pattern on the ribbons, instead of inking a homogeneous layer of material, in which one can print ink on the ribbon in such a way to transfer already a part of a circuit or an entire circuit, for example such as a RFID or any other design (e.g., as required for packaging discrete devices on a substrate). FIG. 6 illustrates a substrate 601 onto which a patterned circuit 606 may be transferred. A laser 603 may be utilized, to emit a laser beam 604 onto a ribbon 605 with a pattern, such as a repeating pattern, 602 deposited thereon, such as with a metallic ink or paste. Or, any equivalent detachment means may be utilized. Note that the ribbon 605 may be dispensed from as ribbon magazine (not shown). The result is that the repeating pattern 606 is transferred onto the substrate 601. Similarly, a laser raster can be used whereby the laser beam moves or the ribbon moves or both move depending on the application.

Another embodiment is flashing a source of energy, for example IR, through a mask on the top of the ribbon in such a way as to transfer specific patterns onto the substrate.

More complex circuits or a combination of different ribbons may be utilized to make extensive and complicated circuits on a substrate in order to achieve any type of complex circuitry by using the concept of transfer processes from a ribbon.

Furthermore, an embodiment may include a ribbon that is moving continuously under a reservoir of ink/paste such that the coating is fresh and immediate on the ribbon, in which thereafter the coating is applied onto a substrate.

It is known that the large LCD TV manufacturers would like to have a low cost process and realize metallic lines (currently focusing on copper) on their substrates in order to improve the quality of the images on the screen. If one wants copper lines, it would he very expensive and difficult to deposit thick layers of copper on an entire glass substrate and then etch the copper such that only required lines will be left on a substrate. By applying a ribbon, for example, with a copper ink/paste/thin film, one can use this type of ribbon to have a very low cost process that can be easily integrated with the high volume production rate needed for the LCD TV industry. Knowing some of the limitations described above, copper coated ribbons with complementary external agents may be utilized in order to transfer the seed layer of copper to a glass substrate and then plate these seed layers as described, herein to a desired thickness, achieving a desired electrical property.

In the case of laser sintering of copper ink/paste, for example, during the transfer process from the ribbon to the substrate the ink is already sintered such that the feature on the substrate is already copper. An alternative is, depending on the laser power or exterior agent technology, to transfer copper ink/paste to the glass or other desired substrate and then use a sintering method adequate for the specific substrate, either thermal, laser, xenon flash, ultrasound or any other type of sintering.

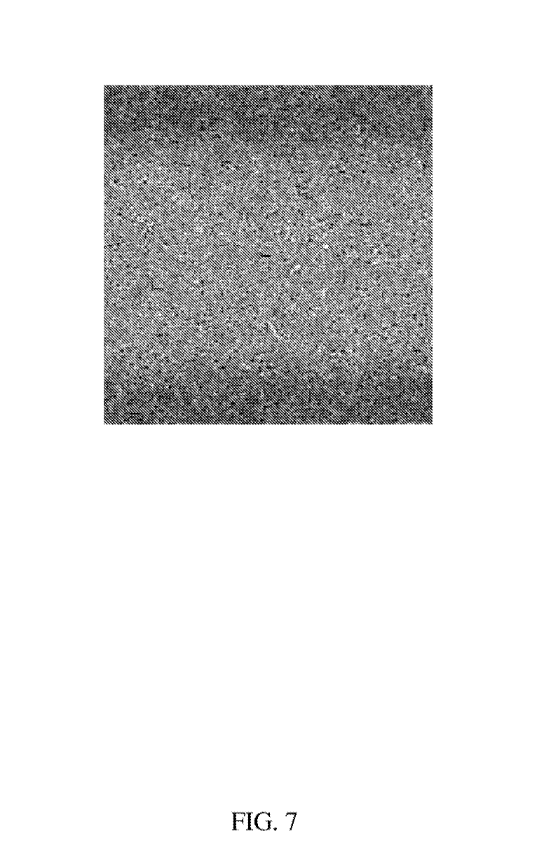

FIG. 7 is a digital image of a copper ink/paste sintered a low power laser. The sintered layer (which in this example is 10 micrometers wide) can be observed by its bright color (although the laser beam was wider than 10 micrometers due to its Gaussian tail). The reason is that, when the power of the laser is suitable, achieved is excellent sintering while, when the power is not strong enough, the sintering process is not complete or even not exercised at all.

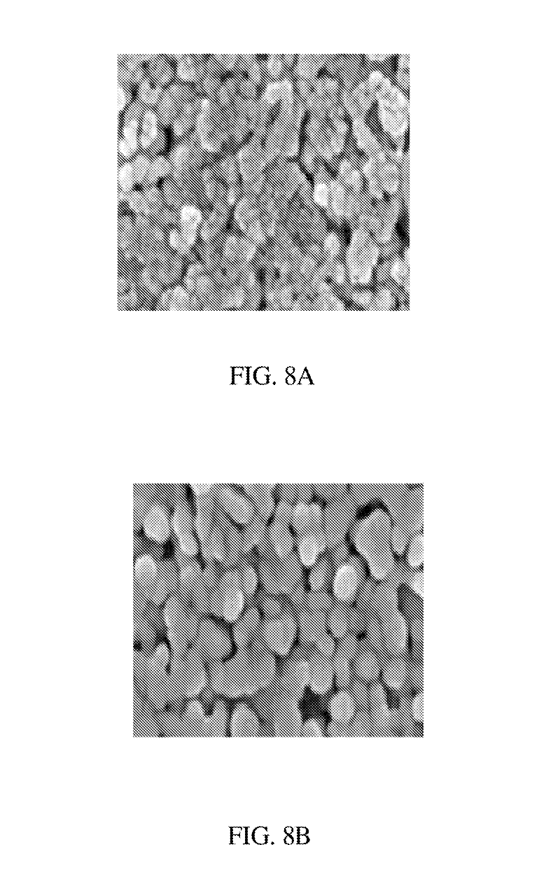

FIG. 8A shows a digital image (at the same scale) of the morphology of a sintered region of copper ink/paste, while FIG. 8B shows the morphology of an unsintered region of copper ink/paste. In FIG. 8A, the average grain size is approximately 50 nanometers; in FIG. 8B, the average grain size is approximately 200 nanometers.

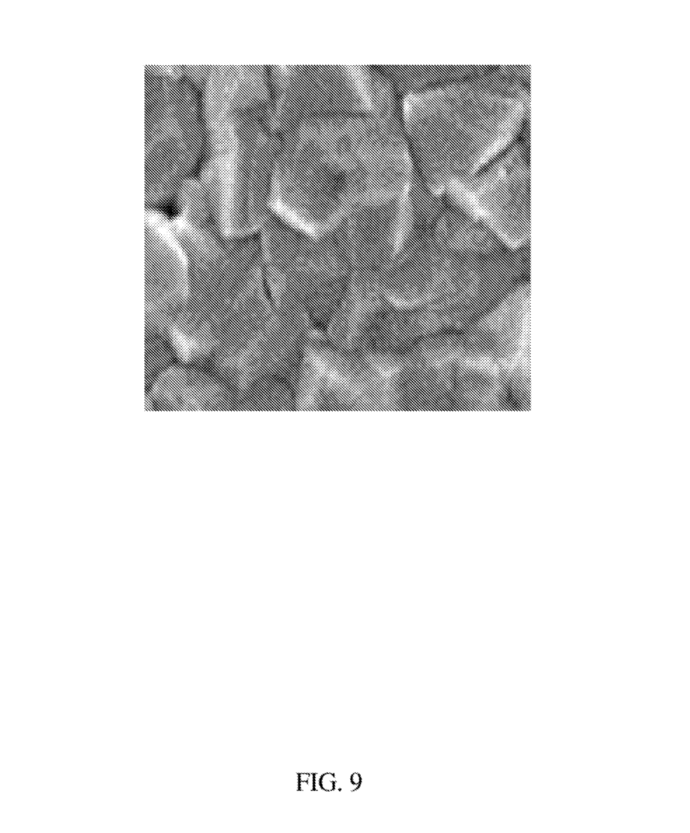

This case demonstrated that the shape of the laser beam, the scanning rate, the pulse width, the power, and the surrounding gas at the location of the sintering are important for the end result. For example, once the threshold for sintering is achieved, a morphology as in FIG. 8A was obtained; but, as the power increased and if the sintering takes place in air, for example, achieved was a morphology characteristic to copper oxide that had very high resistivity, as shown in FIG. 9. In FIG. 9, the average crystallite size is approximately 250×100 nanometers.

These dependencies of the sintering process may be exploited to start from one type of material (in the exemplified case copper ink/paste) and, using smart transfer processes and smart sintering processes, one can achieve on a substrate different kinds of materials from ink/paste feature to a new material trace on the substrate; in the exemplified case, this can be a highly resistive metallic layer, a low resistive metallic layer, something in between, or even an insulative layer.

For solar cell manufacturing, metallization is a very important and complicated process. Many techniques are used for metalizing solar cells, such as evaporation, spattering, coating, spraying, etc., each with its own advantages and disadvantages. The largest disadvantage of these techniques is cost and the final result of electrical conductivity of the metal traces and the contact resistance between the metallic trace and the silicon material directly or through a dielectric layer. Another embodiment of the invention disclosed herein is to do this by metallic ribbons, which only apply a gentle pressure on the silicon wafer, in such a way allowing the thickness of the wafer to be smaller for lowering the manufacturing cost.

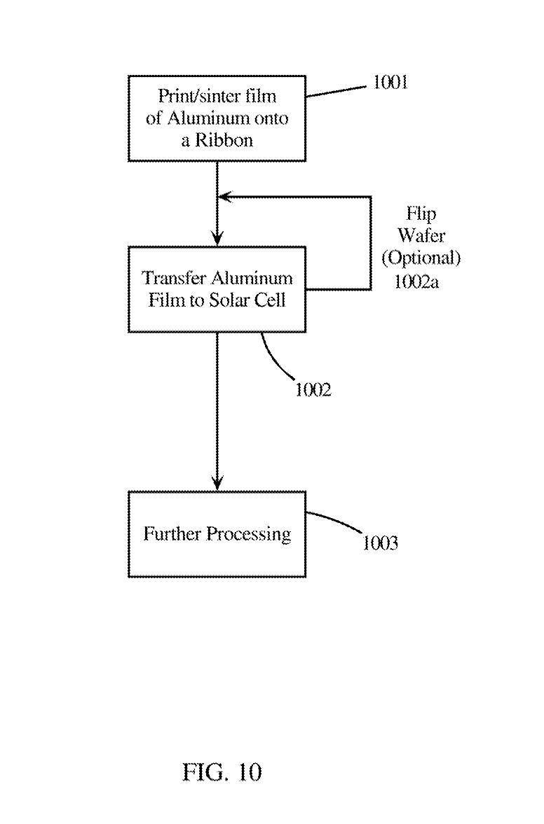

In an example, referring to FIG. 10, a silicon solar cell was prepared for metallization. A film of aluminum paste may be processed onto a ribbon by printing and sintering (step 1001). The aluminum film may be transferred to the backside of a solar cell using a laser transfer process (step 1002). The wafer may then be flipped over exposing the topside of the wafer. A secondary film ribbon containing silver ink (or nickel or copper) may be placed in close proximity to the solar wafer. A laser transferred a grid structure pattern from the metal ribbon to the solar cell (step 1002a). The solar cell may then be thermal processed to establish an electrical contact at less than 400° C. (step 1003).

In another example, similar steps may be performed to prepare a silicon solar cell with alternating n- and p-domains creating an interdigitated pattern on the backside of the wafer. The ribbon transfer process may be used to transfer a single metal in an exact pattern matching the n- and p-regions of the wafer respectively. The metal used may be Al, Ni, or Cu. The wafer may be then thermal processed to establish an electrical contact at less than 400° C.

In another example similar to the previous one, an interdigitated back contact silicon solar cell may be processed using a laser transfer technique. Two ribbons of different metals may be used such that different metals are placed onto the n- and p-type sections of the wafer, respectively. For example, Al may be used on the p-type domains, and Ni (or Ag or Cu) may be used on the n-type domains.

What is claimed:

1. A method comprising:
printing a metallic ink material onto a flexible ribbon dispensed from a ribbon magazine in a position over a substrate:
transferring the metallic ink from the ribbon to the substrate using an external detachment means; and
transforming the metallic ink transferred to the substrate into a conductive layer.

2. The method as recited in claim 1, wherein the metallic ink is deposited on the ribbon with a release layer that is suitable to release the metallic, ink from the ribbon by the external detachment means.

3. The method as recited in claim 2, wherein the transforming further comprises a sintering of the transferred metallic ink.

4. The method as recited in claim 2, wherein the transforming further comprises photosintering of the transferred metallic ink.

5. The method as recited in claim 2, wherein the detachment means comprises a laser emitting a laser beam at the ribbon to detach the copper ink.

6. The method as recited in claim 2, wherein the detachment means further comprises a thermal release process.

7. The method as recited in claim 1, further comprising drying the metallic ink before it is detached from the ribbon.

8. The method as recited in claim 1, wherein the substrate is a silicon wafer.

9. The method as recited in claim 8, wherein the silicon wafer further comprises at least one solar cell.
